(19) United States
(12) Patent Application Publication
(10) Pub. No.: US 2007/0194313 A1
(43) Pub. Date: Aug. 23, 2007

(54) Array substrate for liquid crystal display panel

(76) Inventor: Young-Bae Jung, Hwaseong-si (KR)

Correspondence Address: CANTOR COLBURN, LLP, 55 GRIFFIN ROAD SOUTH, BLOOMFIELD, CT, 06002, US

(21) Appl. No.: 11/652,838

(22) Filed: Jan. 12, 2007

(30) Foreign Application Priority Data
Feb. 20, 2006 (KR) 2006-001-6063

(51) Int. Cl. H01L 29/04

(52) U.S. Cl. 257/59

(57) ABSTRACT

An array substrate includes a substrate including a display area and a peripheral area, a thin film transistor formed in the display area and a capacitor formed in the peripheral area. The capacitor includes a first sub-capacitor and a second sub-capacitor. The first sub-capacitor includes a lower electrode layer, a middle electrode layer formed on the lower electrode layer and a first dielectric layer disposed between the lower electrode layer and the middle electrode layer. The second sub-capacitor is disposed on the first sub-capacitor and includes the middle electrode layer, an upper electrode layer formed on the middle electrode layer and a second dielectric layer disposed between the middle electrode layer and the upper electrode layer.

This application claims priority to Korean Patent Application No. 2006-0016063 filed on Feb. 20, 2006, and all the benefits accruing therefrom under 35 U.S.C. §119, the contents of which are herein incorporated by reference in its entirety.

### BACKGROUND OF THE INVENTION

1. Field of the Invention

The present invention relates to an array substrate for a liquid crystal display panel. More particularly, the present invention relates to an array substrate for a liquid crystal display panel capable of increasing a capacitance of a capacitor.

2. Description of the Related Art

In general, a liquid crystal display (“LCD”) apparatus displays images using optical and electrical characteristics of liquid crystals. The LCD apparatus has various characteristics such as a light weight, a low power consumption rate and requiring a low driving voltage for its operation, etc. The LCD apparatus is used in various fields of the related industry.

The LCD apparatus includes an LCD panel having an array substrate, a color filter substrate facing the array substrate and a liquid crystal layer disposed between the array substrate and the color filter substrate. Moreover, the array substrate has a plurality of thin film transistors, a plurality of gate wirings and a plurality of drain wirings.

A driving circuit for driving the thin film transistors is formed on a printed circuit board (“PCB”), and is electrically connected to the array substrate through a tape carrier package (“TCP”). The driving circuit is formed directly on the peripheral area of the array substrate.

The array substrate having the driving circuit on the array substrate further includes a capacitor that stabilizes a voltage or pumps a charge.

In order to increase the capacitance of the capacitor, the area of the capacitor is increased. When a non-display area or a peripheral area of the LCD panel is small, the size of the capacitor is restricted, thereby also restricting the capacitance of the capacitor.

Therefore, it becomes critical to have a method for increasing the capacitance of the capacitor in a restricted area.

### BRIEF SUMMARY OF THE INVENTION

Exemplary embodiments provide an array substrate capable of minimizing an area of a capacitor and increasing a capacitance of the capacitor.

Exemplary embodiments also provide an array substrate capable of simplifying a manufacturing process and increasing a capacitance of a capacitor.

In an exemplary embodiment, an array substrate includes a display area having a plurality of pixel portions and a peripheral area adjacent to the display area, a thin film transistor formed in the display area and having a gate electrode, a source and drain electrodes and a capacitor formed in the peripheral area having a first sub-capacitor and second sub-capacitor.

The first sub-capacitor includes a lower electrode, a middle electrode layer formed on the lower electrode layer and a first dielectric layer disposed between the lower electrode layer and the upper electrode layer.

The second sub-capacitor disposed on the first sub-capacitor includes the middle electrode layer, an upper electrode layer formed on the middle electrode layer, and a second dielectric layer disposed between the middle electrode layer and the upper electrode layer.

In an exemplary embodiment, the lower electrode layer of the first sub-capacitor may be formed by a layer substantially the same as the gate electrode of the thin film transistor. The middle electrode layer may be formed by a layer substantially the same as the source and drain electrodes of the thin film transistor.

In an exemplary embodiment, the array substrate further includes a gate insulation layer formed on the gate electrode of the thin film transistor. The first dielectric layer of the first sub-capacitor may be formed by a layer substantially the same as the gate insulation layer.

In an exemplary embodiment, the array substrate further includes a transparent electrode electrically connected with the drain electrode of the thin film transistor. The upper electrode layer of the second sub-capacitor may be formed by a layer substantially the same as the transparent electrode.

In an exemplary embodiment, the array substrate further includes a passivation layer formed on the source and drain electrodes of the thin film transistor. The second dielectric layer of the second sub-capacitor may be formed from a layer substantially the same as the passivation layer.

In an exemplary embodiment, when the array substrate further includes a reflective electrode on the thin film transistor, the upper electrode of the second sub-capacitor may be formed from a layer substantially the same as the reflective electrode.

In an exemplary embodiment, the lower electrode layer of the first sub-capacitor and the upper electrode layer of the second sub-capacitor are electrically connected. The first sub-capacitor and second sub-capacitor are electrically connected in parallel with each other.

In an exemplary embodiment, an array substrate includes a substrate including a display area with a plurality of pixel portions and a peripheral area adjacent to the display area, a thin film transistor formed in the display area and including a gate electrode, a source electrode and a drain electrodes, a capacitor formed in the peripheral area and including a first and second sub-capacitors, and a pad part formed in the peripheral area to apply a voltage to the capacitor.

The first sub-capacitor includes a lower electrode layer, a middle electrode layer formed on the lower electrode layer, and a first dielectric layer disposed between the lower electrode layer and the middle electrode layer.

The second sub-capacitor includes the middle electrode layer, an upper electrode layer formed on the middle electrode layer and a second dielectric layer disposed between the middle electrode layer and the upper electrode layer.

In an exemplary embodiment, the pad part includes a first pad that is electrically connected to the lower electrode layer of the first sub-capacitor and the upper electrode layer of the second sub-capacitor, and a second pad that is electrically connected to the middle electrode layer.

In an exemplary embodiment, the lower electrode layer of the first sub-capacitor and the upper electrode layer of the second sub-capacitor are electrically connected to the first pad, so that the first and second sub-capacitors are electrically connected in parallel with each other.

In an exemplary embodiment, the array substrate further includes a first voltage supply wiring extended from the lower electrode layer of the first sub-capacitor and the lower electrode layer. The first pad may be electrically connected through the first voltage supply wiring. The first pad includes a first pad electrode extended from the first voltage supply wiring.

In an exemplary embodiment, the lower electrode layer of the first sub-capacitor, the first voltage supply wiring and the first pad electrode may be formed from a layer substantially the same as the gate electrode of the thin film transistor.

In an exemplary embodiment, the array substrate may further include a third voltage supply wiring extended from the upper electrode layer of the second sub-capacitor, and the first pad may further include a first cover electrode extended from the third voltage supply wiring.

In an exemplary embodiment, when the array substrate further includes a transparent electrode electrically connected to the drain electrode of the thin film transistor, the upper electrode layer of the second sub-capacitor, the third voltage supply wiring and the first cover electrode may be formed from a layer substantially the same as the transparent electrode.

In an exemplary embodiment, the first pad may further include a first middle layer disposed between the first pad electrode and the first cover electrode, and the first middle layer may be formed from a layer substantially the same as the first dielectric layer of the first sub-capacitor. When the array substrate further includes a gate insulation layer formed on the gate electrode, the first dielectric layer and the first middle layer of the first sub-capacitor may be formed from a layer substantially the same as the gate insulation layer.

In an exemplary embodiment, the first pad may be exposed through a first contact hole of the first middle layer, and the first pad electrode may make contact with the first cover electrode through the first contact hole.

In an exemplary embodiment, when the array substrate further includes a reflective electrode on the thin film transistor, the upper electrode layer of the second sub-capacitor and the third voltage supply wiring may be formed from a layer substantially the same as the reflective electrode.

In an exemplary embodiment, the array substrate may further include a second voltage supply wiring extended from the middle electrode layer, the middle electrode layer may be electrically connected to the second pad through the second voltage supply wirings. The second pad may include a second pad electrode extended from the second voltage supply wiring.

In an exemplary embodiment, the middle electrode layer, the second voltage supply wiring and the second pad electrode may be formed from a layer substantially the same as the source and drain electrodes of the thin film transistor.

In an exemplary embodiment, the second pad may further include a second cover electrode formed on the second pad electrode. When the array substrate further includes a transparent electrode electrically connected to the drain electrode of the thin film transistor, the second cover electrode may be formed from a layer substantially the same as the transparent electrode.

In an exemplary embodiment, an array substrate includes a substrate having a display area with a plurality of pixel portions and a peripheral area adjacent to the display area; a thin film transistor formed in the display area of the substrate and including a gate electrode, a source electrode and a drain electrode, and a capacitor formed in the peripheral area and including a first sub-capacitor, a second sub-capacitor, and a contact part.

The first sub-capacitor includes a lower electrode layer, a middle electrode layer formed on the lower electrode layer and a first dielectric layer disposed between the lower electrode layer and the middle electrode layer.

The second sub-capacitor is disposed on the first sub-capacitor and includes the middle electrode layer, an upper electrode layer is formed on the middle electrode layer, and a second dielectric layer is disposed between the middle electrode layer and the upper electrode layer.

The contact part is formed through the first dielectric layer of the first sub-capacitor and the second dielectric layer of the second sub-capacitor. The lower electrode layer of the first sub-capacitor makes contact with the upper electrode layer of the second sub-capacitor through the contact part, so that the first sub-capacitor is electrically connected in parallel with the second sub-capacitor.

In an exemplary embodiment, the array substrate includes the capacitor having a structure in parallel with the first sub-capacitor in the lower portion and the second sub-capacitor in the upper portion, so that the capacitance of the capacitor may be increased without enlarging the area of the capacitor.

When the gate electrode and the source/drain electrodes of the thin film transistor, or the transparent electrode or the reflective electrode is formed, each of the electrodes in the first and second sub-capacitors may be formed simultaneously, thereby completing the capacitor having the high capacitance.

### BRIEF DESCRIPTION OF THE DRAWINGS

The above and other advantages of example embodiment of the present invention will become readily apparent by reference to the following detailed description when considered in conjunction with the accompanying drawings wherein:

FIG. 1 is a diagrammatic plan view illustrating an exemplary embodiment of an array substrate in accordance with the present invention;

FIG. 2 is an enlarged plan view illustrating an exemplary embodiment of a capacitor and a pixel portion in FIG. 1;

FIG. 3 is a cross-sectional view taken along line I-I′ in FIG. 2;

FIG. 4 is a plan view illustrating capacitances of first and second sub-capacitors that are shown in FIG. 2 and electrically connected in parallel with each other;

FIG. 5 is an enlarged plan view illustrating another exemplary embodiment of a capacitor and a pixel portion of an array substrate in accordance with the present invention;

FIG. 6 is a cross-sectional view taken along line II-II′ in FIG. 5;

FIG. 7 is an enlarged plan view illustrating another exemplary embodiment of a capacitor and a pixel portion of an array substrate in accordance with the present invention; and

FIG. 8 is a cross-sectional view taken along line III-III′ in FIG. 7.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiment of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” relative to other elements or features would then be oriented “upper” relative to the other elements or features. Thus, the exemplary term“lower” can encompass both an orientation of upper and lower. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

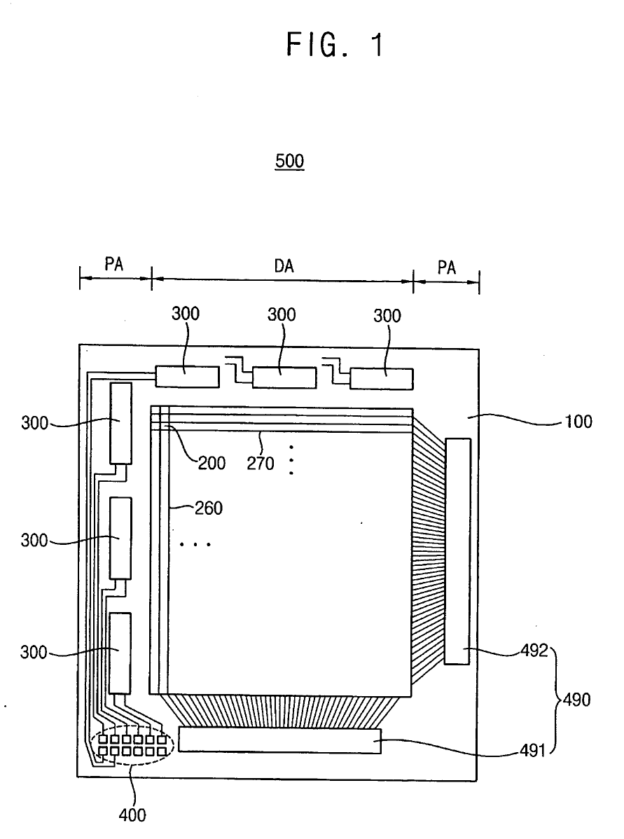

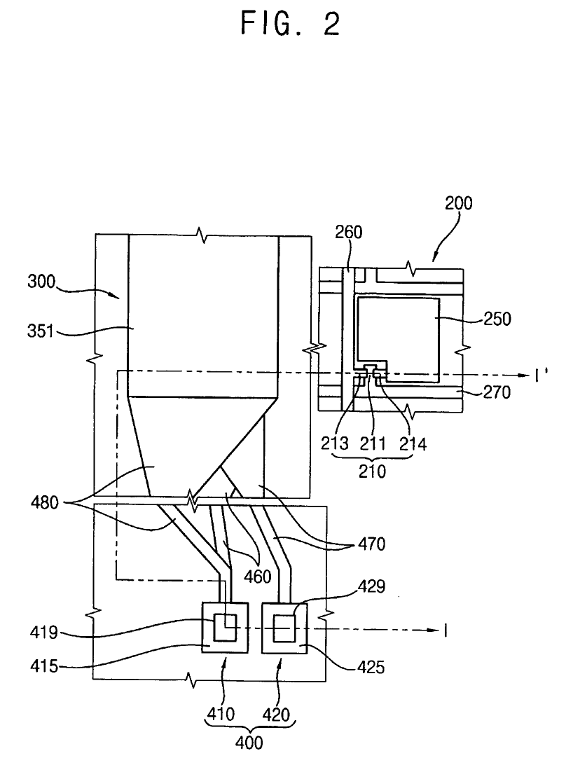

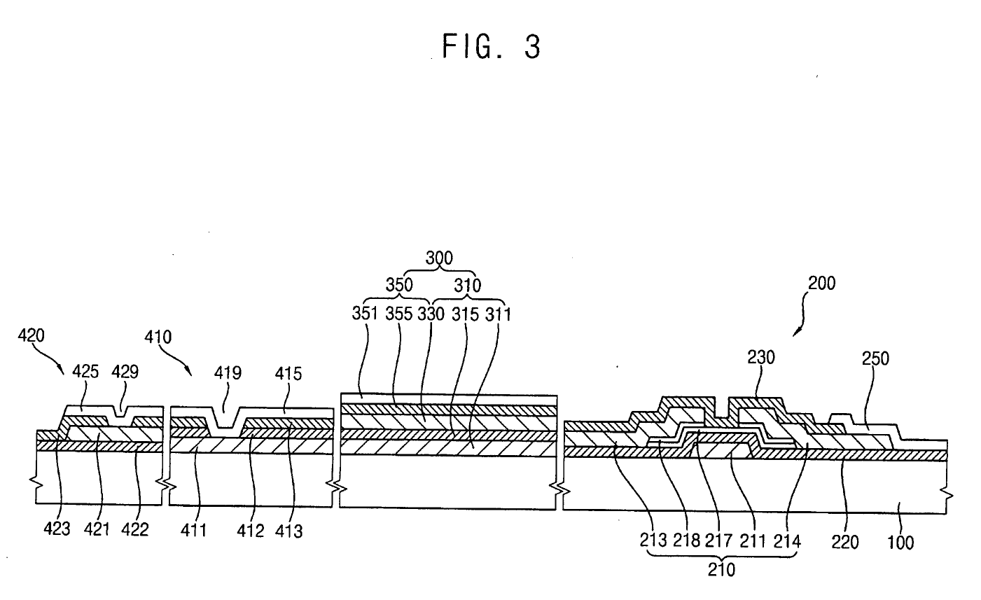

FIG. 1 is a diagrammatic plan view illustrating an exemplary embodiment of an array substrate in accordance with the present invention. FIG. 2 is an enlarged plan view illustrating a capacitor and a pixel portion in FIG. 1. FIG. 3 is a cross-sectional view taken along line I-I′ in FIG. 2.

Referring FIGS. 1 to 3, an array substrate 500 includes a substrate 100 having a display area DA and a peripheral area PA, a thin film transistor 210 formed in the display area DA of the substrate 100 and a capacitor 300 formed in the peripheral area PA of the substrate 100.

The display area DA of the substrate 100 includes a plurality of pixel portions 200 defined by a plurality of gate lines 260 and a plurality of data lines 270. The thin film transistor 210 is formed in each of the pixel portions 200.

The thin film transistor 210 includes a gate electrode 211 electrically connected to one of the gate lines 260 a source electrode 213 electrically connected to one of the data lines 270 and a drain electrode 214. The thin film transistor 210 may further include an amorphous silicon layer 217 and an N+ amorphous silicon layer 218 formed between the source/drain electrodes 213 and 214 and the gate electrode 211.

A gate insulation layer 220 is formed on the gate electrode 211 of the thin film transistor 210. In an exemplary embodiment, the gate insulation layer 220 may include silicon nitride or silicon oxide. A passivation layer 230 may be formed on the source and drain electrodes 213 and 214 of the thin film transistor 210. In an exemplary embodiment, the passivation layer 230 may include silicon nitride, silicon oxide or organic insulation material.

A transparent electrode 250 is formed on each of the pixel portions 200 of the display area DA. The transparent electrode 250 is electrically connected to the drain electrode 214 of the thin film transistor 210. In exemplary embodiments, the transparent electrode 250 may include transparent conductive material. The transparent conductive materials that may be used for the transparent electrode 250 include, but are not limited to, indium tin oxide (“ITO”), indium zinc oxide (“IZO”), zinc oxide (“ZO”), etc. These materials can be used alone or in a combination thereof.

A driving circuit part 490 driving the thin film transistor 210 may be formed in the peripheral area PA of the substrate 100. In one exemplary embodiment, the driving circuit part 490 may be divided into a gate driving part 491 electrically connected to the gate lines 260 and a data driving part 492 electrically connected to the data lines 270. In an alternative embodiment, the gate driving part 491 and the data driving part 492 may be formed in one driving circuit part.

At least one capacitor 300 is formed in the peripheral area PA of the substrate 100. In an exemplary embodiment, the capacitor 300 may be used in a circuit stabilizing a voltage applied to the driving circuit part 490 or used in the thin film transistor 210. In an alternative exemplary embodiment, the capacitor 300 may be used as a flying capacitor of a charge pump circuit to raise or invert a voltage applied to the display panel.

Referring to FIG. 3, the capacitor 300 includes a first sub-capacitor 310 disposed on a lower portion of the capacitor 300 and a second sub-capacitor 350 disposed on an upper portion of the capacitor 300.

The first sub-capacitor 310 includes a lower electrode layer 311, a middle electrode layer 330 formed on the lower electrode layer 311 and a first dielectric layer 315 formed between the lower electrode layer 311 and the middle electrode layer 330.

The second sub-capacitor 350 includes the middle electrode layer 330, an upper electrode layer 351 formed on the middle electrode layer 330 and a second dielectric layer 355 formed between the middle electrode layer 330 and the upper electrode layer 351.

Each of the lower electrode layers 311, the middle electrode layer 330 and the upper electrode layer 351 may include metal and/or a transparent conductive material. Exemplary embodiments of the metal include, but are not limited to, copper, aluminum, etc. Exemplary embodiments of the transparent conductive material include, but are not limited to, indium tin oxide, indium zinc oxide, etc.

In an exemplary embodiment, in order to simplify a manufacturing process, the gate electrode 211 of the thin film transistor 210, the source and drain electrodes 213 and 214 or the transparent electrode 250 of the thin film transistor 210 may be formed from a layer substantially the same as the lower electrode layer 311, the middle electrode layer 330 or the upper electrode layer 351.

In one exemplary embodiment, the lower electrode layer 311 of the first sub-capacitor 310 may be formed from a layer substantially the same as the gate electrode 211 of the thin film transistor 210. The middle electrode layer 330 may be formed from a layer substantially the same as the source/drain electrodes 213 and 214 of the thin film transistor 210.

The upper electrode layer 351 of the second sub-capacitor 350 may be formed from a layer substantially the same as the transparent electrode 250. In addition, the array substrate 500 may further include a reflective electrode (not shown), and the upper electrode layer 351 of the second sub-capacitor 350 may be formed from a layer substantially the same as the reflective electrode.

In order to form the first dielectric layer 315 and the second dielectric layer 355 through the simplified manufacturing process, the first dielectric layer 315 of the first sub-capacitor 310 may be formed from a layer substantially the same as the gate insulation layer 220 and the second dielectric layer 355 of the second sub-capacitor 350 may be formed from a layer substantially the same as the passivation layer 230.

The array substrate 500 may further include a pad part 400 formed in the peripheral area PA of the substrate 100 to apply a voltage to the capacitor 300.

As in the illustrated embodiments, the pad part 400 includes a first pad 410 and a second pad 420. The first pad 410 is electrically connected to the lower electrode layer 311 of the first sub-capacitor 310 and the upper electrode 351 of the second sub-capacitor 350. The second pad 420 is electrically connected to the middle electrode layer 330.

The first pad 410 is electrically connected to the lower electrode layer 311 of the first sub-capacitor 310 through a first voltage supply wiring 460 extended from the lower electrode layer 311. However, the first pad 410 may be electrically connected to the lower electrode layer 311 by various methods. In one exemplary embodiment, the connecting wiring may not be extended from the lower electrode layer 311 of the first sub-capacitor 310 and the first pad 410 may be electrically connected to the lower electrode layer 311 through an additional wiring.

When the first pad 410 is electrically connected to the lower electrode layer 311 of the first sub-capacitor 310 through the first voltage supply wiring 460 extended from the lower electrode layer 311, the first pad 410 may include the first pad electrode 411 extended from the first voltage supply wiring 460, thereby completing the lower electrode layer 311 of the first sub-capacitor 310, the first voltage supply wiring 460 and the first pad electrode 411.

In an exemplary embodiment, the lower electrode layer 311, the first voltage supply wiring 460 and the first pad electrode 411 may be formed from a layer substantially the same as the gate electrode 211 of the thin film transistor 210.

The first pad 410 may be electrically connected to the upper electrode layer 351 of the second sub-capacitor 350 through a third voltage supply wiring 480 extended from the upper electrode layer 351.

In an exemplary embodiment, the upper electrode layer 351 of the second sub-capacitor 350 and the third voltage supply wiring 480 extended from the upper electrode layer 351 may be formed from a layer substantially the same as the transparent electrode 250.

The first pad 410 may further include a first cover electrode 415 formed on the first pad electrode 411. The first cover electrode 415 reduces or effectively prevents the first pad electrode 411 from generating corrosion. Advantageously, a corrosion resistance of the first pad electrode 410 is increased by the first cover electrode 415.

The first cover electrode 415 may include a material having a high corrosion resistance and a high electrical conductivity. Exemplary embodiments of the material that may be used for the first cover electrode 415 include, but are not limited to, indium tin oxide (“ITO”), indium zinc oxide (“IZO”), etc.

In an exemplary embodiment, when the upper electrode layer 351 of the second sub-capacitor 350 and the third voltage supply wiring 480 extended from the upper electrode layer 351 are formed from a layer substantially the same as the transparent electrode 250, the first cover electrode 415 may be extended from the third voltage supply wiring 480. The upper electrode layer 351 of the third voltage supply wiring 480 and the first cover electrode 415 are thereby completed.

The first pad 410 may further include a first middle layer 412 formed between the first pad electrode 411 and the first cover electrode 415. In exemplary embodiments, the first middle layer 412 may be formed from a layer substantially the same as the first dielectric layer 315 of the first sub-capacitor 310. The first dielectric layer 315 of the first sub-capacitor 310 and the first middle layer 412 may be formed from a layer substantially the same as the gate insulation layer 220. Moreover, a third middle layer 413 may be formed between the first middle layer 412 and the first cover electrode 415.

As in the illustrated embodiment, the first pad electrode 411 of the first pad 410 is electrically connected to the first cover electrode 415 of the first pad 410 through a first contact hole 419 that is formed through the first middle layer 412. The first pad 410 is electrically connected to the lower electrode layer 311 of the first sub-capacitor 310. The first pad 410 is also electrically connected to the upper electrode layer 351 of the second sub-capacitor 350, thereby electrically connecting the lower electrode layer 311 and the upper electrode layer 351 of the capacitor 300.

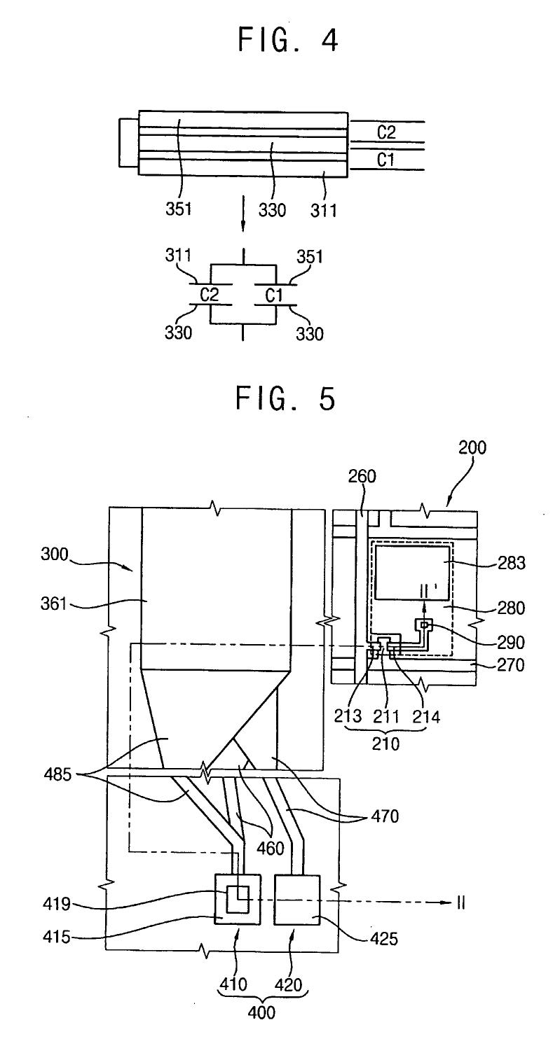

FIG. 4 is a plan view illustrating a capacitance of first and second sub-capacitors shown in FIG. 2 and being electrically connected in parallel with each other.

As illustrated in FIG. 4, the lower electrode layer 311 is electrically connected to the upper electrode layer 351, and the first sub-capacitor 310 is electrically connected in parallel with the second sub-capacitor 350.

When two sub-capacitors 310 and 350 are electrically connected in parallel with each other, a total capacitance of the connected capacitors is substantially equal to a summation of capacitances of the capacitors. In one exemplary embodiment, the capacitance of the capacitor 300 is substantially equal to a summation of a capacitance C1 of the first sub-capacitor 310 and a capacitance C2 of the second sub-capacitor 350. The second sub-capacitor 350 is disposed on the first sub-capacitor 310 and the first and second sub-capacitors 310 and 350 are electrically connected in parallel with each other, such that the total capacitance of the capacitor 300 increased although the area of the capacitor 300 is not increased.

Referring again to FIGS. 2 and 3, the second pad 420 may be electrically connected to the middle electrode layer 330 through a second voltage supply wiring 470 extended from the middle electrode layer 330. However, the second pad 420 may be electrically connected to the middle electrode layer 330 through various methods. In one exemplary embodiment, the connecting wiring may not be extended from the middle electrode layer 330 and the second pad 420 may be electrically connected to the middle electrode layer 330 through an extra wiring.

When the second pad 420 is electrically connected to the middle electrode layer 330 through the second voltage supply wiring 470 extended from the middle electrode layer 330, the second pad 420 may include the second pad electrode 421 extended from the second voltage supply wiring 470. The middle electrode layer 330, the second voltage supply wiring 470 and the second pad electrode 421 are thereby completed.

In an exemplary embodiment, the middle electrode layer 330, the second voltage supply wiring 470 and the second pad electrode 421 may be formed from a layer substantially the same as the source/drain electrodes 213 and 214 of the thin film transistor 210.

The second pad 420 may further include a second cover electrode 425 on the second pad electrode 421. The second cover electrode 425 reduces or effectively prevents the second pad electrode 421 from generating corrosion. Advantageously corrosion resistance of the second pad electrode 420 may be increased by the second cover electrode 425.

The second cover electrode 425 may include a material having a high corrosion resistance and a high electrical conductivity. Exemplary embodiments of the material that may be used for the second cover electrode 425 include, but are not limited to, indium tin oxide (“ITO”), indium zinc oxide (“IZO”), etc.

The second pad 420 may further include a second middle layer 423 formed between the second pad electrode 421 and the second cover electrode 425. In exemplary embodiments, the second middle layer 423 may be formed from a layer substantially the same as the second dielectric layer 355 of the second sub-capacitor 350. The second dielectric layer 355 of the second sub-capacitor 350 and the second middle layer 423 may be formed from a layer substantially the same as the passivation layer 230.

A fourth middle layer 422 may be formed between the second middle layer 423 and the substrate 100. The second cover electrode 425 may make contact with the second pad electrode 421 through a second contact hole 429 that is formed through the second middle layer 423 of the second pad 420.

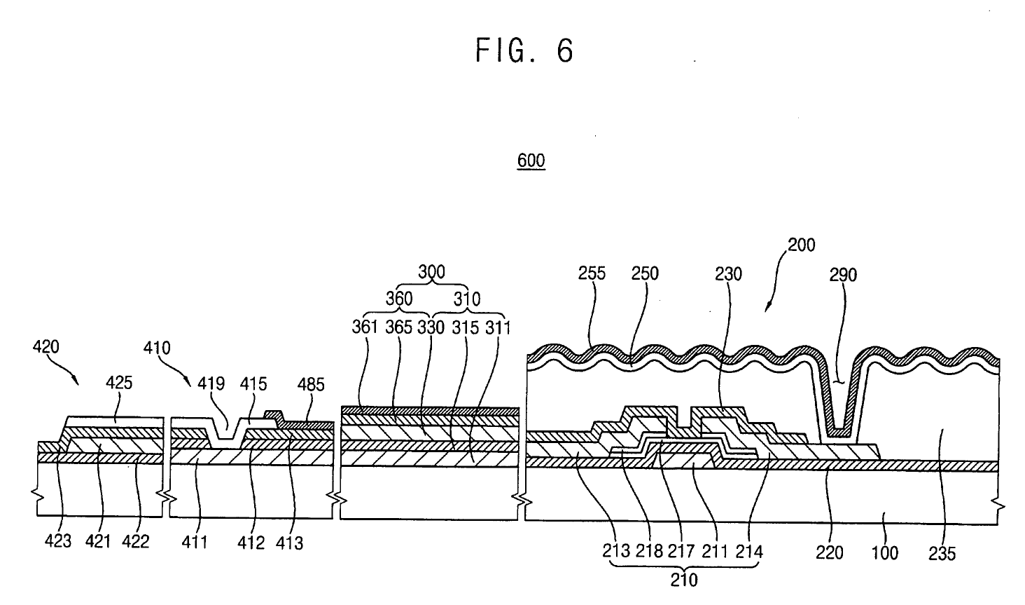

FIG. 5 is an enlarged plan view illustrating another exemplary embodiment of a capacitor and a pixel portion of an array substrate in accordance with the present invention. FIG. 6 is a cross-sectional view taken along line II-II′ in FIG. 5.

Referring to FIGS. 5 and 6, an array substrate 600 includes a substrate 100 having a display area and a peripheral area, a thin film transistor 210 formed in the display area of the substrate 100, and a capacitor 300 formed in the peripheral area of the substrate 100.

A position of the capacitor 300 on the array substrate 600 in FIGS. 5 and 6 is substantially the same as a position of the capacitor 300 on the array substrate 500 in FIG. 1. Thus, the explanation concerning the position of the capacitor 300 on the array substrate 600 in FIGS. 5 and 6 in accordance with the present embodiment will be omitted. Moreover, the same reference numerals will be used to refer to the same or like parts of the array substrate 500 as those described in FIGS. 1 to 3, and any further explanation concerning the above elements will be omitted.

As in the illustrated embodiment, the pixel portion 200 in FIG. 2 is for a transmissive-type LCD panel. Alternatively, a pixel portion 200 in FIG. 5 is for a transflective-type LCD panel.

The pixel 200 includes a transmissive window 283 and a reflective area 280. The transmissive window 283 transmits light provided from a rear side, and the reflective area 280 reflects light provided from a front side. The pixel portion 200 in FIG. 6 illustrates a portion of a cross-section of the reflective area 280.

A thin film transistor 210 is formed in the reflective area 280 of the pixel portion 200. The thin film transistor 210 includes a gate electrode 211, a source electrode 213 and a drain electrode 214. The thin film transistor 210 may further include an amorphous silicon layer 217 and an N+ amorphous silicon layer 218 formed between the source/drain electrodes 213 and 214 and the gate electrode 211.

A gate insulation layer 220 may be formed on the gate electrode 211 of the thin film transistor 210, and a passivation layer 230 may be formed on the source/drain electrodes 213 and 214 of the thin film transistor 210.

An organic insulation layer 235 is formed on the thin film transistor 210. The upper surface of the organic insulation layer 235 may be patterned as a wave shape to improve a reflectivity of a reflective electrode 255 formed on the organic insulation layer 235.

A transparent electrode 250 is formed on the upper surface of the organic insulation layer 235. The transparent electrode 250 includes transparent and conductive material. The reflective electrode 255 is formed on the transparent electrode 250. In exemplary embodiments, the reflective electrode 255 may include molybdenum (Mo)—aluminum (Al) alloy, molybdenum (Mo)—tungsten (W) alloy or aluminum (Al)—neodymium (Nd) alloy. In an alternative embodiment, the reflective electrode 255 may be directly formed on the upper surface of the organic insulation layer 235.

The transparent electrode 250 and the reflective electrode 255 are electrically connected to the drain electrode 214 of the thin film transistor 210 through a third contact hole 290 formed through the organic insulation layer 235.

The capacitor 300 includes a first sub-capacitor 310 and a second sub-capacitor 360 disposed on the first sub-capacitor 310.

Referring to FIG. 6, the first sub-capacitor 310 includes a lower electrode layer 311, a middle electrode layer 330 formed on the lower electrode layer 311 and a first dielectric layer 315 formed between the lower electrode layer 311 and the middle electrode layer 330.

The second sub-capacitor 360 includes the middle electrode layer 330, an upper electrode layer 361 formed on the middle electrode layer 330 and a second dielectric layer 365 disposed between the middle electrode layer 330 and the upper electrode layer 361.

The gate electrode 211 of the thin film transistor 2100, the source/drain electrodes 213 and 214 of the thin film transistor 210, the transparent electrode 250 or the reflective electrode 255 may be formed with the lower electrode layer 311, the middle electrode layer 330 and the upper electrode layer 361, so that an additional manufacturing process may not be required.

In one exemplary embodiment, the lower electrode layer 311 of the first sub-capacitor 310 may be formed from a layer substantially the same as the gate electrode 211 of the thin film transistor 210, and the middle electrode layer 330 may be formed from a layer substantially the same as the source/drain electrodes 213 and 214 of the thin film transistor 210.

In the illustrated embodiment, the upper electrode layer 361 of the second sub-capacitor 360 is formed from a layer substantially the same as the reflective electrode 255.

The array substrate 600 includes a first pad 410 electrically connected to the lower electrode layer 311 of the first sub-capacitor 310 and the upper electrode layer 361 of the second sub-capacitor 360, and a second pad 420 electrically connected to the middle electrode layer 330.

The first pad 410 may be electrically connected to the lower electrode layer 311 through a first voltage supply wiring 460 that is extended from the lower electrode layer 311 of the first sub-capacitor 310. The first pad 410 may include a first pad electrode 411 extended from the first voltage supply wiring 460. In an exemplary embodiment, the lower electrode layer 311, the first voltage supply wiring 460 and the first pad electrode 411 may be formed from a layer substantially the same as the gate electrode 211 of the thin film transistor 210.

The first pad 410 may further include a first cover electrode 415 formed on the first pad electrode 411. The first cover electrode 415 may include a material having a high corrosion resistance and a high electric conductivity. Exemplary embodiments of the material that may be used for the first cover electrode 415 include, but are not limited to, indium tin oxide (“ITO”), indium zinc oxide (“IZO”), etc.

The first cover electrode 415 of the first pad 410 may be electrically connected to the upper electrode layer 361 through a fourth voltage supply wiring 485 extended from the upper electrode layer 361 of the second sub-capacitor 360.

In one exemplary embodiment, when the upper electrode layer 361 of the second sub-capacitor 360 is formed from a layer substantially the same as the reflective electrode 255, the fourth voltage supply wiring 485 may also be formed from a layer substantially the same as the reflective electrode 255.

As in the illustrated embodiment, the array substrate 600 includes a first pad 410 connecting the lower electrode layer 311 of the first sub-capacitor 310 and the upper electrode layer 361 of the second sub-capacitor 360, and a second pad 420 electrically connected to the middle electrode layer 330.

The first sub-capacitor 310 and the second sub-capacitor 360 are electrically connected in parallel with each other, thereby increasing the capacitance of the capacitor 300 as described in FIG. 4, although the area of the capacitor 300 is not increased.

Except for what is mentioned above, the structure of the first pad 410 of the present embodiment is substantially the same as the first pad 410 in FIG. 4, and thus any further explanations concerning the above elements will be omitted.

The second pad 420 of the present embodiment is substantially the same as the second pad 420 in FIG. 4 except for the second contact hole 429 (shown in FIG. 3), and thus any further explanation concerning the above elements will be omitted. In an alternative, embodiment, the second pad 420 may include the second contact hole 429 as illustrated in FIG. 3.

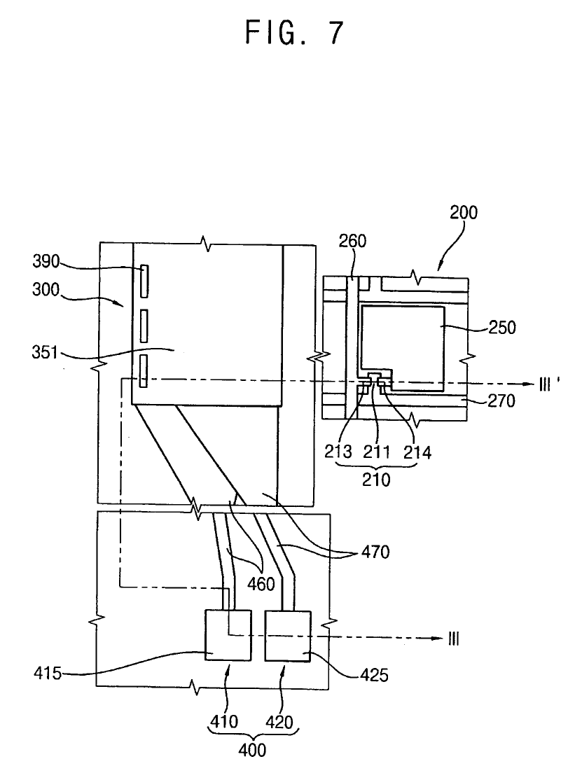

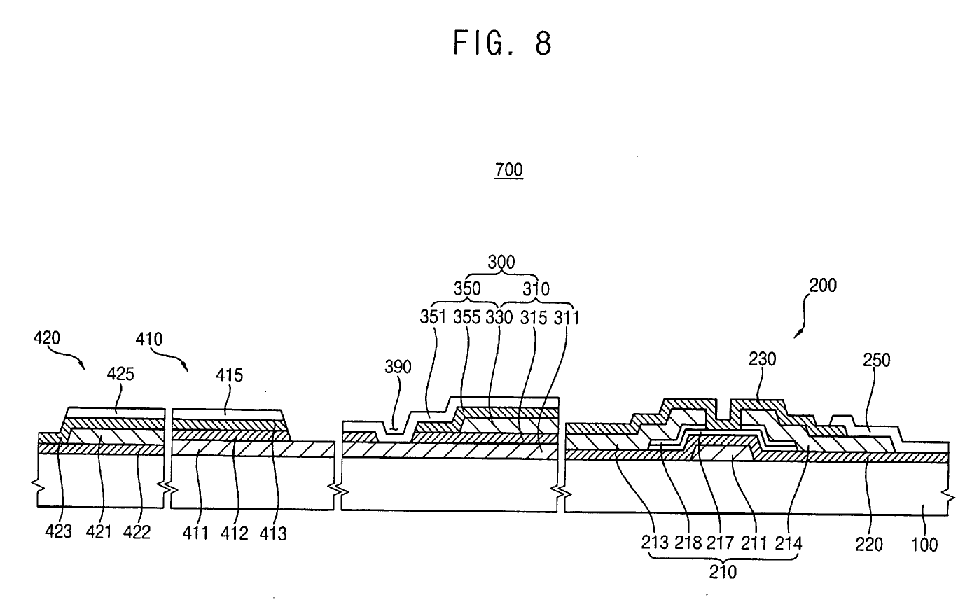

FIG. 7 is an enlarged plan view illustrating another exemplary embodiment of a capacitor and a pixel portion of an array substrate in accordance with the present invention. FIG. 8 is a cross-sectional view taken along line III-III′ in FIG. 7.

Referring FIGS. 7 and 8, an array substrate 700 includes a substrate 100 having a display area and a peripheral area, a thin film transistor 210 formed in the display area of the substrate 100 and the capacitor 300 formed in the peripheral area of the substrate 100.

A position of the capacitor 300 on the array substrate 700 in FIGS. 7 and 8 is substantially the same as a position of the capacitor 300 on the array substrate 500 in FIG. 1. Thus, the discussion concerning the position of the capacitor 300 on the array substrate 700 in FIGS. 7 and 8 in accordance with the present embodiment will be omitted. Moreover, the same reference numerals will be used to refer to the same or like parts of the array substrate 500 as those described in FIGS. 1 to 3, and thus any further explanation concerning the above elements will be omitted.

The capacitor 300 includes a first sub-capacitor 310 disposed on a lower portion of the capacitor 300 and a second sub-capacitor 350 disposed on an upper portion of the capacitor 300.

The first sub-capacitor 310 includes a lower electrode layer 311, a middle electrode layer 330 formed on the lower electrode layer 330 and a first dielectric layer 315 formed between the lower electrode layer 311 and the middle electrode layer 330.

The second sub-capacitor 350 includes the middle electrode layer 330, an upper electrode layer 351 formed on the middle electrode layer 330 and a second dielectric layer 355 formed between the middle electrode layer 330 and the upper electrode layer 351.

The capacitor 300 may further include at least one contact part 390 formed through the first dielectric layer 315 of the first sub-capacitor 310 and the second dielectric layer 355 of the second sub-capacitor 350.

In the present embodiment, the contact part 390 is formed outside of the capacitor 300. However, a position of the contact part 390 may be changed. In an alternative exemplary embodiment, the contact part 390 may be formed inside of the capacitor 300.

The lower electrode layer 311 of the first sub-capacitor 310 may make contact with the upper electrode layer 351 of the second sub-capacitor 350 through the contact part 390, thereby, connecting the first sub-capacitor 310 and the second sub-capacitor 350 in parallel with each other. As a result, as described in FIG. 4, the capacitance of the capacitor 300 may be increased, although the area of the capacitor 300 is not increased.

The gate electrode 211 of the thin film transistor 210, the source/drain electrodes 213 and 214 of the thin film transistor 210, the transparent electrode 250 and/or the reflective electrode 255 may be simultaneously formed with the middle electrode layer 330 and the upper electrode layer 351, so that an additional manufacturing process may not be required.

In one exemplary embodiment, the lower electrode 311 of the first sub-capacitor 310 may be formed from a layer substantially the same as the gate electrode 211 of the thin film transistor 210, and the middle electrode 330 may be formed from a layer substantially the same as the source/drain electrodes 213 and 214 of the thin film transistor 210.

Moreover, the upper electrode layer 351 of the second sub-capacitor 350 may be formed from a layer substantially the same as the transparent electrode 250. In an alternative embodiment, when the array substrate 500 further includes a reflective electrode (not shown), the upper electrode layer 351 of the second sub-capacitor 350 may be formed from a substantially same layer as the reflective electrode (not shown).

The array substrate 700 includes a first pad 410 electrically connected to the lower electrode layer 311 of the first sub-capacitor 310, and a second pad 420 electrically connected to the middle electrode layer 330.

The first pad 410 may be electrically connected to the lower electrode layer 311 through a first voltage supply wiring 460 extended from the lower electrode layer 311 of the first sub-capacitor 310. The first pad 410 may include a first pad electrode 411 extended from the first voltage supply wiring 460. In an exemplary embodiment, the lower electrode layer 311, the first voltage supply wiring 460 and the first pad electrode 411 may be formed from a layer substantially the same as the gate electrode 211 of the thin film transistor 210.

Referring to FIG. 7, the second pad 420 may be electrically connected to the upper electrode layer 351 through a second voltage supply wiring 470 extended from the upper electrode layer 351 of the second sub-capacitor 350. The second pad 420 may include a second pad electrode 421 extended from the second voltage supply wiring 470. The upper electrode layer 351, the second voltage supply wiring 470 and the second pad electrode 421, for example, may be formed from a layer substantially the same as the source/drain electrodes 213 and 214 of the thin film transistor 210.

The first pad 410 may further include a first cover electrode 415 formed on the first pad electrode 411. The second pad 420 may further include a second cover electrode 425 formed on the second pad electrode 421.

The first and second cover electrodes 415 and 425 reduce or effectively prevent the first and second pad electrodes 411 and 421 from generating corrosion Advantageously, corrosion resistances of the first and second pads 410 and 420 are increased by the first and second cover electrodes 415 and 425, respectively.

The first and second cover electrodes 415 and 425 may include a material having a high corrosion resistance and a high electrical conductivity. Exemplary embodiments of the material that may be used for the first and second cover electrodes 415 and 425 include, but are not limited to, indium tin oxide (“ITO”), indium zinc oxide (“IZO”), etc.

The first and second pads 410 and 420 of the present embodiment is substantially the same as the first and second pads 410 and 420 in FIG. 4 except for the first and second contact holes 419 and 429 (shown in FIG. 3), and thus any further explanation concerning the above elements will be omitted. In an alternative embodiment, the first pad 410 and/or the second pad 420 may include the first contact hole 419 and/or the second contact hole 429 as illustrated in FIGS. 3 and 5.

As in the illustrated embodiments, the array substrate in includes the second sub-capacitor electrically connected in parallel with the first sub-capacitor, so that the total capacitance of the first and second sub-capacitors may be increased, although, the area of the first and second sub-capacitors is not increased. The first sub-capacitor is formed on the second sub-capacitor.

In the illustrated exemplary embodiments, the gate electrode and the source/drain electrodes of the thin film transistor, the transparent electrode or the reflective electrode may be simultaneously formed with the electrodes of the first and second sub-capacitors, so that the total capacitance of the first and second sub-capacitors may be increased. Advantageously, an additional process is not required.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An array substrate comprising:
a substrate including a display area including a plurality of pixel portions and a peripheral area adjacent to the display area;
a thin film transistor formed in the display area and including a gate electrode, a source electrode and a drain electrode; and
a capacitor formed in the peripheral area, and including;
a first sub-capacitor including a lower electrode layer, a middle electrode layer formed on the lower electrode layer and a first dielectric layer disposed between the lower electrode layer and the middle electrode layer; and
a second sub-capacitor disposed on the first sub-capacitor and including the middle electrode layer, an upper electrode layer formed on the middle electrode layer and a second dielectric layer disposed between the middle electrode layer and the upper electrode layer.

2. The array substrate of claim 1, wherein the lower electrode layer is formed from substantially the same layer as the gate electrode.

3. The array substrate of claim 2, wherein the middle electrode layer is formed from substantially the same layer as the source and drain electrodes.

4. The array substrate of claim 3, further comprising a gate insulation layer formed on the gate electrode, wherein the first dielectric layer is formed from substantially the same layer as the gate insulation layer.

5. The array substrate of claim 3, further comprising a transparent electrode electrically connected with the drain electrode, wherein the upper electrode layer is formed from substantially the same layer as the transparent electrode.

6. The array substrate of claim 5, further comprising a passivation layer formed on the source and drain electrodes, wherein the second dielectric layer is formed from substantially the same layer as the passivation layer.

7. The array substrate of claim 3, further comprising a reflective electrode formed on the thin film transistor, wherein the upper electrode is formed from substantially the same layer as the reflective electrode.

8. The array substrate of claim 1, wherein the lower electrode layer and the upper electrode layer are electrically connected to each other, so that the first and second sub-capacitors are electrically connected in parallel with each other.

9. An array substrate comprising:
a substrate including a display area including a plurality of pixel portions and a peripheral area adjacent to the display area;
a thin film transistor formed in the display area and including a gate electrode, a source electrode and a drain electrode;
a capacitor formed in the peripheral area and including a first sub-capacitor and a second sub-capacitor disposed on the first sub-capacitor; and
a pad part formed in the peripheral area applying a voltage to the capacitor.

10. The array substrate of claim 9, wherein the first sub-capacitor includes a lower electrode layer, a middle electrode layer formed on the lower electrode layer and a first dielectric layer disposed between the lower electrode layer and the middle electrode layer.

11. The array substrate of claim 10, wherein the second sub-capacitor includes the middle electrode layer, an upper electrode layer formed on the middle electrode layer and a second dielectric layer disposed between the middle electrode layer and the upper electrode layer.

12. The array substrate of claim 11, wherein the pad part comprises:
a first pad electrically connected to the lower electrode and the upper electrode layer; and
a second pad electrically connected to the middle electrode layer.

13. The array substrate of claim 12, wherein the first and second sub-capacitors are electrically connected in parallel with each other.

14. The array substrate of claim 13, further comprising a first voltage supply wiring extended from the lower electrode layer, wherein the lower electrode layer is electrically connected to the first pad through the first voltage supply wiring.

15. The array substrate of claim 14, wherein the first pad comprises a first pad electrode extended from the first voltage supply wiring.

16. The array substrate of claim 15, wherein the lower electrode layer, the first voltage supply wiring and the first pad electrode are formed from substantially the same layer as the gate electrode.

17. The array substrate of claim 15, further comprising a third voltage supply wiring extended from the upper electrode layer.

18. The array substrate of claim 17, wherein the first pad further comprises a first cover electrode extended from the third voltage supply wiring.

19. The array substrate of claim 18, further comprising a transparent electrode electrically connected to the drain electrode, wherein the upper electrode layer, the third voltage supply wiring and the first cover electrode are formed from substantially the same layer as the transparent electrode.

20. The array substrate of claim 18, wherein the first pad further comprises a first middle layer disposed between the first pad electrode and the first cover electrode.

21. The array substrate of claim 20, wherein the first middle layer is formed from substantially the same layer as the first dielectric layer.

22. The array substrate of claim 21, further comprising a gate insulation layer formed on the gate electrode, wherein the first dielectric layer and the first middle layer are formed from substantially the same layer as the gate insulation layer.

23. The array substrate of claim 20, wherein the first pad is exposed through a first contact hole in the first middle layer, and the first pad electrode makes contact with the first cover electrode through the first contact hole.

24. The array substrate of claim 17, further comprising a reflective electrode formed on the thin film transistor, wherein the upper electrode layer and the third voltage supply wiring are formed from substantially the same layer as the reflective electrode.

25. The array substrate of claim 13, further comprising a second voltage supply wiring extended from the middle electrode layer, wherein the middle electrode layer is electrically connected to the second pad through the second voltage supply wiring.

26. The array substrate of claim 25, wherein the second pad comprises a second pad electrode extended from the second voltage supply wiring.

27. The array substrate of claim 26, wherein the middle electrode layer, the second voltage supply wiring and the second pad electrode are formed from substantially the same layer as the source and drain electrodes.

28. The array substrate of claim 27, wherein the second pad further comprises a second cover electrode formed on the second pad electrode.

29. The array substrate of claim 28, further comprising a transparent electrode electrically connected to the drain electrode, wherein the second cover electrode is formed from substantially the same layer as the transparent electrode.

30. An array substrate comprising:
a substrate including a display area including a plurality of pixel portions and a peripheral area adjacent to the display area;
a thin film transistor formed in the display area of the substrate and including a gate electrode, a source electrode and a drain electrode; and
a capacitor formed in the peripheral area and including;
a first sub-capacitor including a lower electrode layer, a middle electrode layer formed on the lower electrode layer and a first dielectric layer disposed between the lower electrode layer and the middle electrode layer;
a second sub-capacitor disposed on the first sub-capacitor and including the middle electrode layer, an upper electrode layer formed on the middle electrode layer and a second dielectric layer disposed between the middle electrode layer and the upper electrode layer; and
a contact part formed through the first dielectric layer and the second dielectric layer, the lower electrode layer making contact with the upper electrode layer through the contact part, such that the first sub-capacitor is electrically connected in parallel with the second sub-capacitor.

31. The array substrate of claim 30, wherein the lower electrode layer is formed from substantially the same layer as the gate electrode.

32. The array substrate of claim 31, wherein the middle electrode layer is formed from substantially the same layer as the source and drain electrodes.

33. The array substrate of claim 32, further comprising a transparent electrode electrically connected to the drain electrode, wherein the upper electrode layer is formed from substantially the same layer as the transparent electrode.

34. The array substrate of claim 32, further comprising a reflective electrode formed on the thin film transistor, wherein the upper electrode layer is formed from a layer substantially the same as the reflective layer.

35. The array substrate of claim 30, further comprising:
a first pad electrically connected to the lower electrode layer; and
a second pad electrically connected to the middle electrode layer.

36. The array substrate of claim 31, further comprising a first voltage supply wiring extended from the lower electrode layer, wherein the lower electrode layer is electrically connected to the first pad through the first voltage supply wiring.

37. The array substrate of claim 36, wherein the first pad comprises a first pad electrode extended from the first voltage supply wiring.

38. The array substrate of claim 37, wherein the lower electrode layer, the first voltage supply wiring and the first pad electrode are formed from substantially the same layer as the gate electrode.

39. The array substrate of claim 38, wherein the first pad further comprises a first cover electrode formed on the first pad electrode.

40. The array substrate of claim 35, wherein the array substrate further comprises a second voltage supply wiring extended from the middle electrode layer, the middle electrode layer being electrically connected to the second pad through the second voltage supply wiring.

41. The array substrate of claim 40, wherein the second pad comprises a second pad electrode extended from the second voltage supply wiring.

42. The array substrate of claim 41, wherein the middle electrode layer, the second voltage supply wiring and the second pad electrode are formed from substantially the same layer as the source and drain electrodes.

43. The array substrate of claim 41, wherein the second pad further comprises a second cover electrode formed on the second pad electrode.
